(19) United States
(12) Patent Application Publication
(10) Pub. No.: US 2024/0258251 A1
(43) Pub. Date: Aug. 1, 2024

(54) POLYIMIDE LAYER DEPRESSIONS BETWEEN METAL PILLARS

(71) Applicant: TEXAS INSTRUMENTS INCORPORATED, Dallas, TX (US)

(72) Inventors: Katleen Fajardo TIMBOL, Allen, TX (US); Rafael Jose Lizares GUEVARA, Angeles (PH)

(21) Appl. No.: 18/161,575

(22) Filed: Jan. 30, 2023

(51) Int. Cl. H01L 23/00

(52) U.S. Cl. CPC H01L 24/02; H01L 24/05; H01L 24/06; H01L 2224/02313; H01L 2224/02333; H01L 2224/0235; H01L 2224/02373; H01L 2224/02375; H01L 2224/02381; H01L 2224/0239; H01L 2224/05553; H01L 2224/05569; H01L 2224/06155; H01L 2224/06159; H01L 2924/01029

(57) ABSTRACT

In some examples, a semiconductor package comprises a semiconductor die including circuitry, a first metal pillar coupled to the circuitry and extending away from the semiconductor die, and a second metal pillar coupled to the circuitry and extending away from the semiconductor die. A distance between the first and second metal pillars does not exceed 100 microns. The package also comprises a polyimide layer covering portions of the first and second metal pillars and covering a region between the first and second metal pillars. The polyimide layer in the region between the first and second metal pillars has a thickness not exceeding 15 microns and lacks a boundary between separate applications of polyimide to the region. The package also includes a mold compound covering the polyimide layer in the region between the first and second metal pillars. The package further includes conductive terminals coupled to the first and second metal pillars and exposed to an exterior of the mold compound.

### BACKGROUND

A semiconductor package may include a semiconductor die and a mold compound to cover the semiconductor die. The package may further include conductive terminals exposed to an exterior surface of the housing. The conductive terminals are coupled to the semiconductor die. The conductive terminals provide electrical pathways between circuitry on the semiconductor die and components (e.g., printed circuit boards) outside of the package.

### SUMMARY

In some examples, a semiconductor package comprises a semiconductor die including circuitry, a first metal pillar coupled to the circuitry and extending away from the semiconductor die, and a second metal pillar coupled to the circuitry and extending away from the semiconductor die. A distance between the first and second metal pillars does not exceed 100 microns. The package also comprises a polyimide layer covering portions of the first and second metal pillars and covering a region between the first and second metal pillars. The polyimide layer in the region between the first and second metal pillars has a thickness not exceeding 15 microns and lacks a boundary between separate applications of polyimide to the region. The package also includes a mold compound covering the polyimide layer in the region between the first and second metal pillars. The package further includes conductive terminals coupled to the first and second metal pillars and exposed to an exterior of the mold compound.

In some examples, a method for manufacturing a semiconductor package comprises forming one or more metal layers in a semiconductor die, the one or more metal layers coupled to circuitry of the semiconductor die; forming first and second metal pillars on the one or more metal layers, the first metal pillar separated from the second metal pillar by a distance not exceeding 100 microns; and applying a polyimide layer to the one or more metal layers and to the first and second metal layers. The method also comprises positioning a reticle above the polyimide layer. The reticle includes a first transmittance area positioned above an area of the polyimide layer on the one or more metal layers, and a second transmittance area positioned above the polyimide layer on the first metal pillar. The reticle also includes a third transmittance area above the polyimide layer on a region between the first and second metal pillars, the third transmittance area having a light transmittance that is in between light transmittances of the first and second transmittance areas. The method further comprises applying light to the polyimide layer through the first, second, and third transmittance areas of the reticle; developing the polyimide layer; soldering the first and second metal pillars to conductive terminals; and covering the semiconductor die and the polyimide layer with a mold compound.

### BRIEF DESCRIPTION OF THE DRAWINGS

FIG. 1A is a profile cross-sectional view of a semiconductor die and a back end of line (BEOL) layer, in accordance with various examples.

FIG. 1B is a top-down view of a BEOL layer on a semiconductor die, in accordance with various examples.

FIG. 1C is a perspective view of a semiconductor die and a BEOL layer, in accordance with various examples.

FIG. 2A is a profile cross-sectional view of a semiconductor die, a BEOL layer on the semiconductor die, and conductive members on the BEOL layer, in accordance with various examples.

FIG. 2B is a top-down view of conductive members on a BEOL layer that is on a semiconductor die, in accordance with various examples.

FIG. 2C is a perspective view of a semiconductor die, a BEOL layer on the semiconductor die, and conductive members on the BEOL layer, in accordance with various examples.

FIG. 3A is a profile cross-sectional view of a semiconductor die, a BEOL layer on the semiconductor die, conductive members on the BEOL layer, and a protective layer on the conductive members and the BEOL layer, in accordance with various examples.

FIG. 3B is a top-down view of a protective layer on conductive members coupled to a BEOL layer, in accordance with various examples.

FIG. 3C is a perspective view of a semiconductor die, a BEOL layer on the semiconductor die, conductive members on the BEOL layer, and a protective layer on the conductive members and the BEOL layer, in accordance with various examples.

FIG. 4 is a profile cross-sectional view depicting photolithography of a protective layer on conductive terminals coupled to a BEOL layer on a semiconductor die, in accordance with various examples.

FIGS. 5A-5C are top-down views of photolithography reticles, in accordance with various examples.

FIG. 6A is a profile cross-sectional view of an exposed and developed protective layer on conductive terminals coupled to a BEOL layer on a semiconductor die, in accordance with various examples.

FIG. 6B is a top-down view of an exposed and developed protective layer on conductive terminals coupled to a BEOL layer on a semiconductor die, in accordance with various examples.

FIG. 6C is a perspective view of an exposed and developed protective layer on conductive terminals coupled to a BEOL layer on a semiconductor die, in accordance with various examples.

FIG. 7A is a profile cross-sectional view of a semiconductor package containing a semiconductor die coupled to a BEOL layer and conductive terminals protected by a protective layer, in accordance with various examples.

FIG. 7B is a bottom-up view of a semiconductor package, in accordance with various examples.

FIG. 7C is a perspective view of a semiconductor package, in accordance with various examples.

FIG. 8A is a profile cross-sectional view of an exposed and developed protective layer on conductive terminals coupled to a BEOL layer on a semiconductor die, in accordance with various examples.

FIG. 8B is a top-down view of an exposed and developed protective layer on conductive terminals coupled to a BEOL layer on a semiconductor die, in accordance with various examples.

FIG. 8C is a perspective view of an exposed and developed protective layer on conductive terminals coupled to a BEOL layer on a semiconductor die, in accordance with various examples.

FIG. 9A is a profile cross-sectional view of an exposed and developed protective layer on conductive terminals coupled to a BEOL layer on a semiconductor die, in accordance with various examples.

FIG. 9B is a top-down view of an exposed and developed protective layer on conductive terminals coupled to a BEOL layer on a semiconductor die, in accordance with various examples.

FIG. 9C is a perspective view of an exposed and developed protective layer on conductive terminals coupled to a BEOL layer on a semiconductor die, in accordance with various examples.

FIG. 10 is a flow diagram of a method for manufacturing a semiconductor package in accordance with various examples.

### DETAILED DESCRIPTION

Some semiconductor dies include redistribution layers (RDLs). RDLs are a network of metal layers above the circuitry of the semiconductor die that operate as an interface between the circuitry of the die and conductive terminals, such as metal (e.g., copper) pillars, solder bumps, etc. RDLs may include polyimide layers to insulate the RDL metal layers from each other. Metal pillars (or posts) couple to the RDL metal layers and extend away from the semiconductor die. The metal pillars may couple to a lead frame by way of solder bumps, for example.

In many applications, the space (or pitch) between consecutive metal pillars may be large (e.g., 400 microns). When a polyimide layer is applied to the region between consecutive, widely-spaced metal pillars, the polyimide layer is relatively thin. As a result, a mold compound that is subsequently applied on the thin polyimide layer has adequate space to flow, thus mitigating the formation of voids (e.g., air pockets) in the mold compound. The space between consecutive metal pillars may be large enough that even a large-filler mold compound does not form a significant number of voids. However, when the space between consecutive metal pillars is small (e.g., fewer than 100 microns), the polyimide layer deposited in the region between the metal pillars is relatively thick. When the mold compound is later applied to this thick polyimide layer, the mold compound does not have adequate space to flow freely, thereby encouraging the formation of voids. Void formation is exacerbated when large-filler mold compounds are used.

This disclosure describes various examples of a technique that resolves the challenges described above. More specifically, the technique entails the use of a modified reticle during photolithography of the polyimide layer. The reticle includes areas that have a light transmittance of approximately 40-50%, and these areas are used to perform photolithography on the polyimide layer in the region between the metal pillars that are positioned close to each other (e.g., fewer than 100 microns apart). The result is a polyimide layer that is significantly thinned in the region between the metal pillars. When a mold compound is later applied to this thinned region of the polyimide layer, the mold compound has adequate space to flow freely, thus significantly mitigating the likelihood that any voids will form. Even large-filler mold compounds (e.g., filler sizes ranging from 10 microns to 30 microns) may be used with minimal or no void formation.

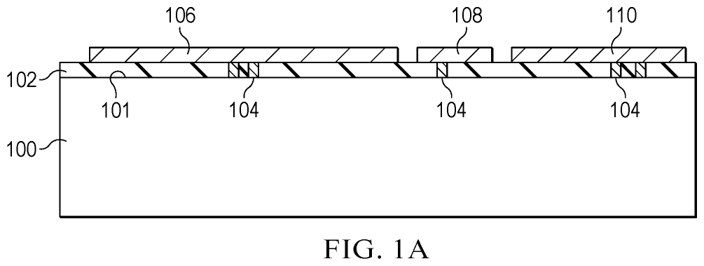

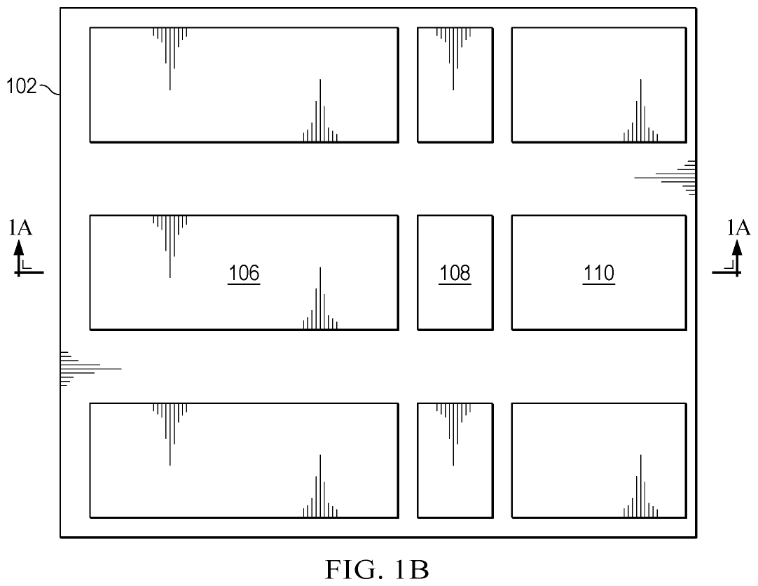

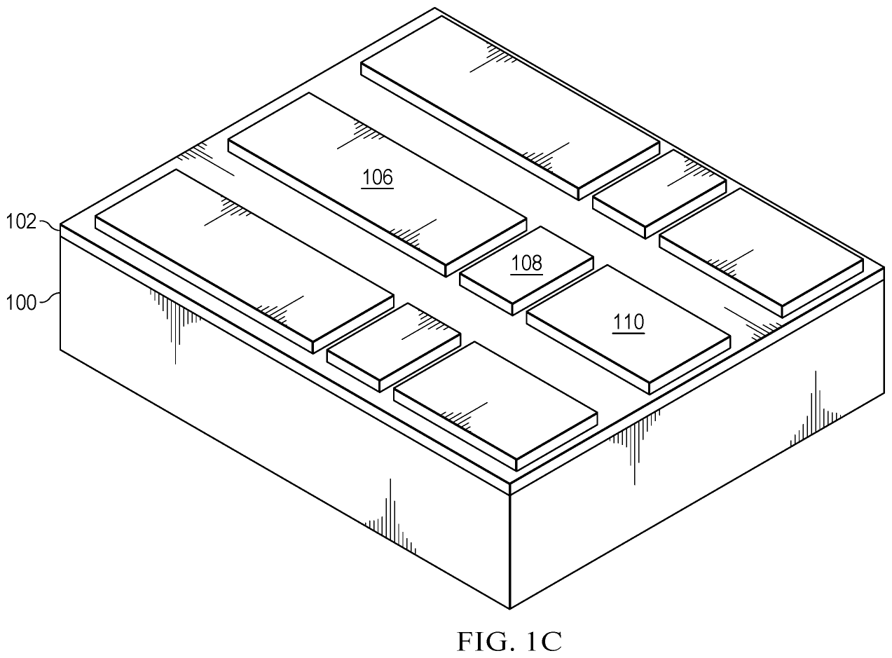

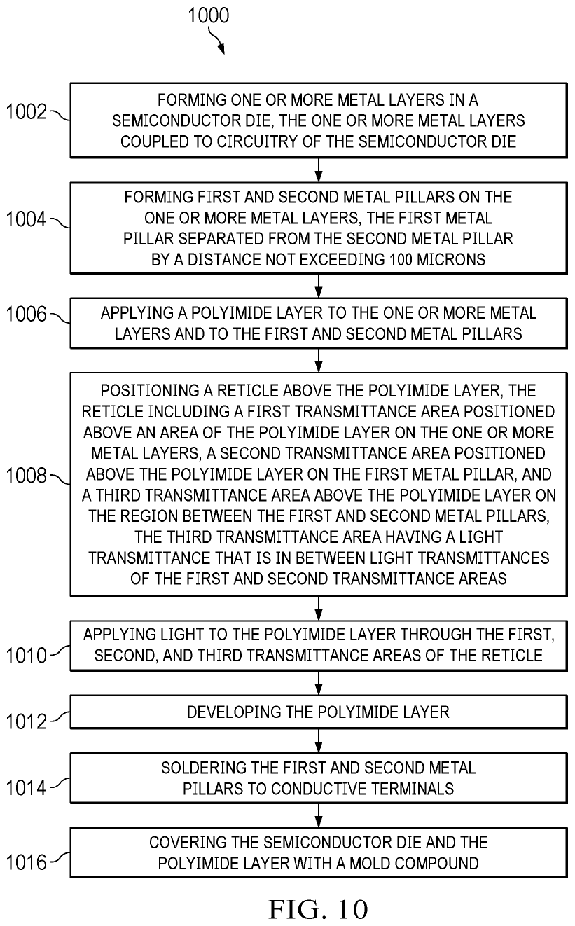

FIGS. 1A-9C are a process flow for manufacturing a semiconductor package in accordance with various examples. FIG. 10 is a flow diagram of a method 1000 for manufacturing a semiconductor package in accordance with various examples. Accordingly, FIGS. 1A-9C and the method 1000 of FIG. 10 are now described in parallel.

The method 1000 includes forming one or more metal layers in a semiconductor die (1002). The one or more metal layers are coupled to circuitry of the semiconductor die (1002). FIG. 1A is a profile cross-sectional view of a semiconductor die and a back end of line (BEOL) layer, in accordance with various examples. Specifically, FIG. 1A shows a semiconductor die 100. The semiconductor die 100 includes various circuitry that operates to perform one or more tasks. FIG. 1A does not expressly show such circuitry. The semiconductor die 100 has a device side 101 in and/or on which such circuitry is formed. FIG. 1A also depicts a passivation layer 102 abutting the device side 101. The passivation layer 102 may include any suitable material, such as silicon oxide or silicon nitride. Vias 104 extend through the passivation layer 102. The vias 104 are conductive and couple to the circuitry on the device side 101. The vias 104 may include tungsten, copper, or other suitable metals or alloys and have a diameter ranging from 0.5 microns to 10 microns. The vias 104 also couple to metal layers 106, 108, and 110. Each metal layer 106, 108, and 110 extends horizontally along the passivation layer 102. In examples, the metal layers 106, 108, and 110 are composed of copper. The metal layers 106, 108, and 110 have thicknesses ranging from 4 microns to 25 microns, with thicker metal layers being disadvantageous because of significantly increased manufacturing costs and aspect ratio limitations, and with thinner metal layers being disadvantageous because of greater electrical resistance.

FIG. 1B is a top-down view of the structure of FIG. 1A, in accordance with various examples. Specifically, FIG. 1B depicts the passivation layer 102 and the metal layers 106, 108, and 110 on the passivation layer 102. As shown, metal layers may be included in addition to the metal layers 106, 108, and 110. FIG. 1C is a perspective view of a semiconductor die and a BEOL layer, in accordance with various examples.

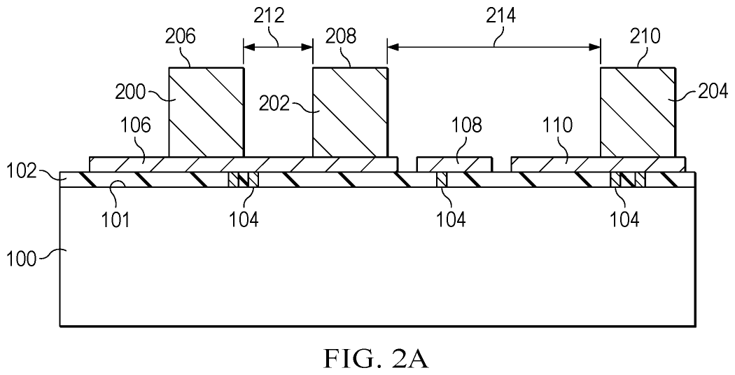

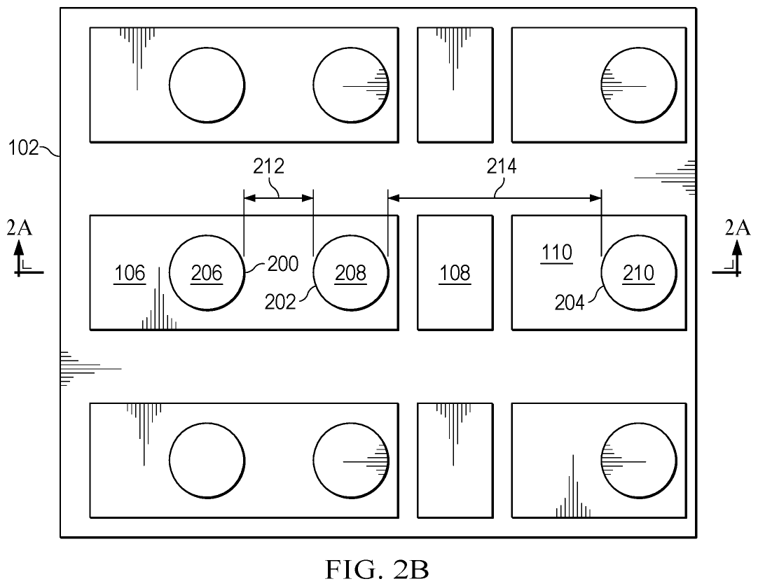

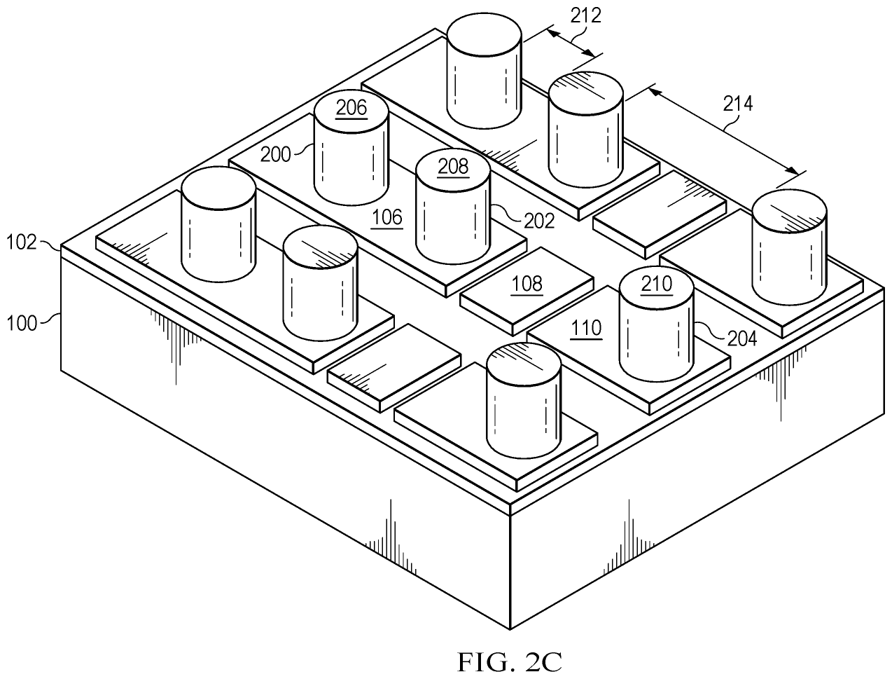

The method 1000 includes forming first and second metal pillars on the one or more metal layers (1004). The first metal pillar is separated from the second metal pillar by a distance not exceeding 100 microns (1004). The techniques described herein are especially useful in applications with small pitch (less than 100 microns) between consecutive metal pillars such that mold compound cannot easily flow and is prone to void formation. FIG. 2A is a profile cross-sectional view of a semiconductor die, a BEOL layer on the semiconductor die, and conductive members on the BEOL layer, in accordance with various examples. Specifically, FIG. 2A shows the structure of FIG. 1A, but with the formation of metal pillars 200, 202, and 204 on the metal layers 106 and 110. The metal pillars 200, 202, and 204 may be composed of any suitable metal or alloy, such as copper. The metal pillars 200, 202, and 204 may be formed using a combination of photolithography and plating (e.g., electroplating) techniques. The metal pillars 200, 202, and 204 have thicknesses ranging from 10 microns to 80 microns, with thicker metal pillars being disadvantageous because of the significantly increased manufacturing costs and increased processing times, and with thinner metal pillars being disadvantageous because of the meaningful limitations to the standoff heights of subsequently deposited solder bumps, and because of the substantial risk of improper mold underfill coverage (e.g., voiding) when a mold compound is later applied. The metal pillars 200, 202, and 204 have top surfaces 206, 208, and 210, respectively. As shown, a gap 212 separates the metal pillars 200 and 202. A gap 214 separates the metal pillars 202 and 204. The gap 212 is less than 100 microns. The gap 214 is equal to or greater than 100 microns.

FIG. 2B is a top-down view of the structure of FIG. 2A, in accordance with various examples. FIG. 2C is a perspective view of the structure of FIG. 2A, in accordance with various examples.

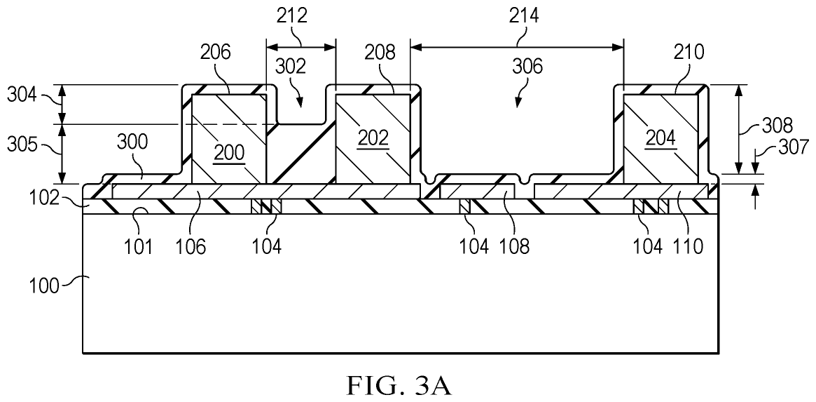

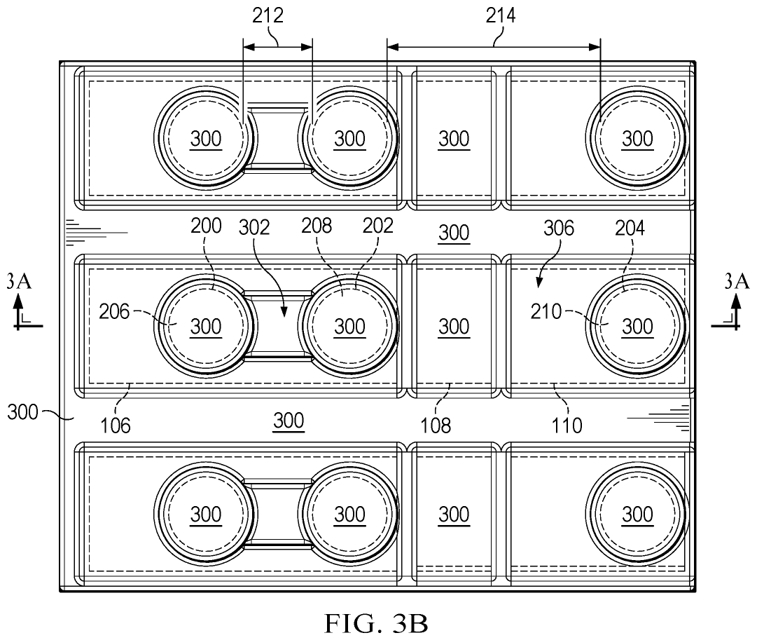

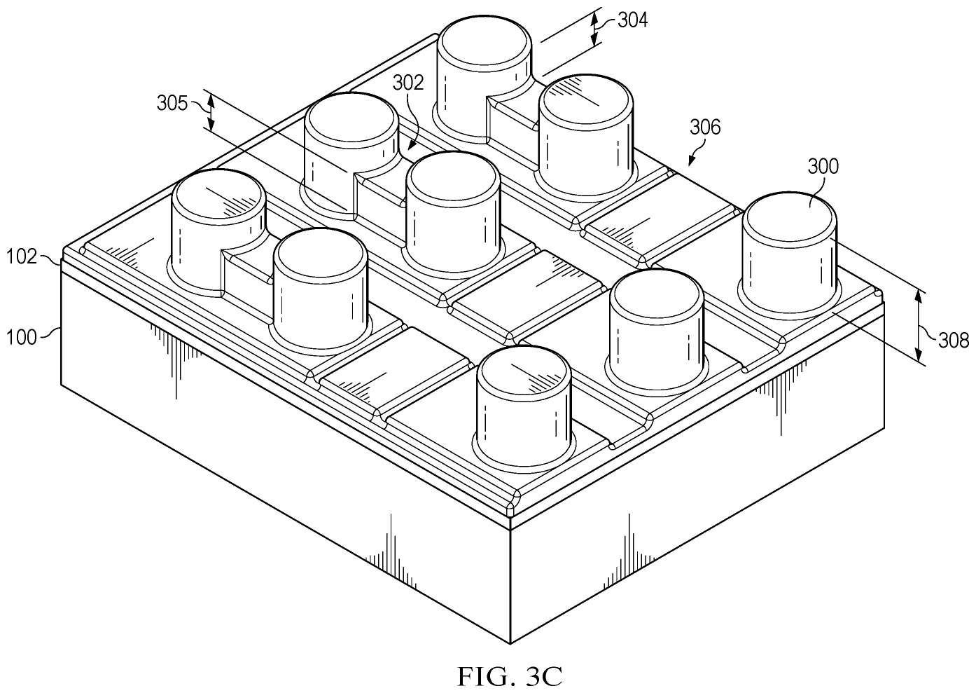

The method 1000 includes applying a polyimide layer to the one or more metal layers and to the first and second metal pillars (1006). FIG. 3A is a profile cross-sectional view of a semiconductor die, a BEOL layer on the semiconductor die, conductive members on the BEOL layer, and a protective layer on the conductive members and the BEOL layer, in accordance with various examples. More specifically, FIG. 3A shows the structure of FIG. 2A, but with the addition of a polyimide layer 300 on the top surface of the structure of FIG. 2A. For example, the polyimide layer 300 covers the metal layers 106, 108, and 110; the passivation layer 102; and the metal pillars 200, 202, and 204. The polyimide layer 300 thickness ranges from 4 microns to 7 microns, with a thicker polyimide layer 300 being disadvantageous because of a significantly increased cost of manufacture, and with a thinner polyimide layer 300 being disadvantageous because of a reduced stress absorption capability and a risk of exposed copper due to diminished or no polyimide coverage. The polyimide layer 300 has a different thickness between the metal pillars 200 and 202, in the gap 212 (FIG. 2A), because of the narrowness of the gap 212 (fewer than 100 microns). The thickness 305 of the polyimide layer 300 in the gap 212 ranges from 25 microns to 35 microns. The polyimide layer 300 in the gap 212 forms a depression 302 with a depth 304 ranging from 15 microns to 25 microns. Conversely, the polyimide layer 300 in the gap 214 (FIG. 2A) between the metal pillars 202 and 204 is thinner than in the gap 212, because the metal pillars 202 and 204 are spaced apart widely (greater than 100 microns). In the gap 214, the thickness 307 of the polyimide layer 300 ranges from 4 microns to 7 microns, forming a depression 306 with a depth 308. The depth 308 ranges from 4 microns to 50 microns.

FIG. 3B is a top-down view of the structure of FIG. 3A, in accordance with various examples. As FIG. 3B shows, the polyimide layer 300 is thickest in the area between each pair of metal pillars 200, 202, and the polyimide layer 300 is thinner in the remaining areas. As described above, the relatively thick polyimide layer 300 between each pair of metal pillars 200, 202 restricts the flow of mold compound and causes the formation of voids in the mold compound. FIG. 3C is a perspective view of the structure of FIG. 3A.

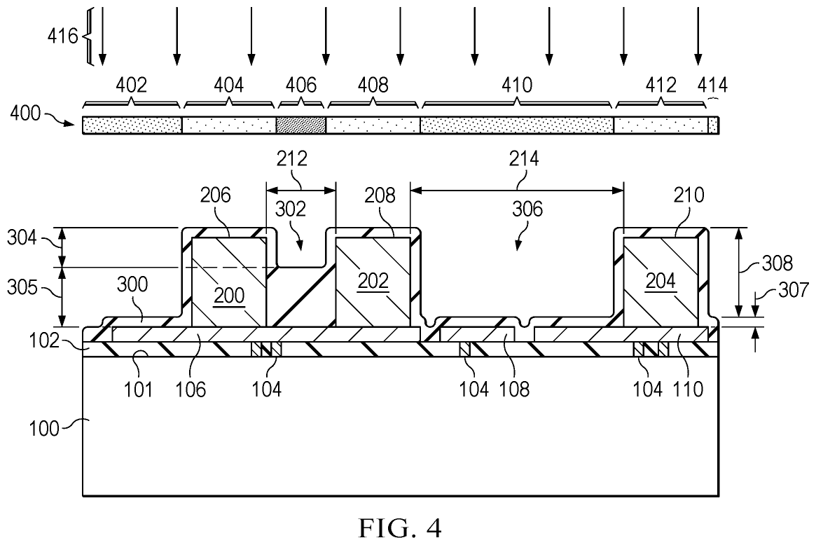

The method 1000 includes positioning a reticle above the polyimide layer (1008). The reticle includes a first transmittance area positioned above an area of the polyimide layer on the one or more metal layers (1008). The reticle includes a second transmittance area positioned above the polyimide layer on the first metal pillar (1008). The reticle includes a third transmittance area above the polyimide layer on the region between the first and second metal pillars (1008). The third transmittance area has a light transmittance that is in between light transmittances of the first and second transmittance areas (1008). FIG. 4 is a profile cross-sectional view depicting photolithography of a protective layer on conductive terminals coupled to a BEOL layer on a semiconductor die, in accordance with various examples. More specifically, FIG. 4 shows a reticle 400 positioned above the structure of FIG. 3A. The reticle 400 includes a light transmittance areas (LTAs) 402, 404, 406, 408, 410, 412, and 414. The polyimide layer 300 may be a negative exposure polyimide, meaning that when subjected to photolithographic processes, exposure to light and developer solution prevents removal of polyimide, and lack of exposure to light and developer solution results in the removal of polyimide. Accordingly, because the areas of polyimide layer 300 directly below the LTAs 402, 410, and 414 are to be maintained and not removed, the light transmittances of the LTAs 402, 410, and 414 may be relatively high. In this way, relatively high amounts of light are applied to the regions of the polyimide layer 300 directly below the LTAs 402, 410, and 414, thereby protecting them from subsequent removal. Because the areas of polyimide layer 300 directly below the LTAs 404, 408, and 412 are to be removed, the light transmittances of the LTAs 404, 408, and 412 are relatively low. In this way, relatively low amounts of light (if any) are applied to the regions of the polyimide layer 300 directly below the LTAs 404, 408, and 412, thereby facilitating the removal of these areas of the polyimide layer 300. Because the area of polyimide layer 300 directly below the LTA 406 is to be partially, but not completely, removed (e.g., to facilitate increased mold flow but to also protect the underlying metal in metal layer 106 from oxidation and other deleterious effects), a modest light transmittance (such as a light transmittance between the light transmittances of the LTAs 404 and 406) may be useful. Thus, the polyimide layer 300 directly below the LTA 406 may be reduced in thickness but not completely eliminated. In some examples, the polyimide layer 300 may be a positive exposure polyimide, meaning that when subjected to photolithographic processes, exposure to light and developer solution causes removal of polyimide, and lack of exposure to light and developer solution prevents removal of polyimide. In such examples, the light transmittance numerical ranges described herein may be reversed. For example, a light transmittance range of 95% to 100% in a negative exposure polyimide application may be replaced with a light transmittance range of 0% to 5% in a positive exposure polyimide application, and vice versa.

More particularly, the LTAs 402, 410, and 414 may have the same degree of light transmittance in the range of 95-100%, with a light transmittance below this range being disadvantageous because it results in reduced polyimide cross-linking and poor polyimide coverage, and with a light transmittance above this range being disadvantageous because it results in an unpatternable polyimide, meaning that the polyimide is desensitized to the chemical(s) used to develop the polyimide. The LTAs 404, 408, and 412 have the same degree of light transmittance, i.e., a light transmittance in the range 0%-5%, with a light transmittance below this range being disadvantageous because it results in inadequate or no light exposure and thus no polyimide coverage, and with a light transmittance above this range being disadvantageous because it results in polyimide scumming. The LTA 406 has a degree of light transmittance in the range of 40%-50%, with a light transmittance below this range being disadvantageous because it results in poor polyimide coverage, and with a light transmittance above this range being disadvantageous because it results in unacceptably large polyimide retention. The LTA 406 is positioned between the LTAs 404 and 408.

The method 1000 includes applying light to the polyimide layer through the first, second, and third transmittance areas of the reticle (1010). Light 416 is applied to the reticle 400, with the light 416 passing through the reticle 400 to the structure underneath the reticle 400 in accordance with the differing light transmittances of the different LTAs.

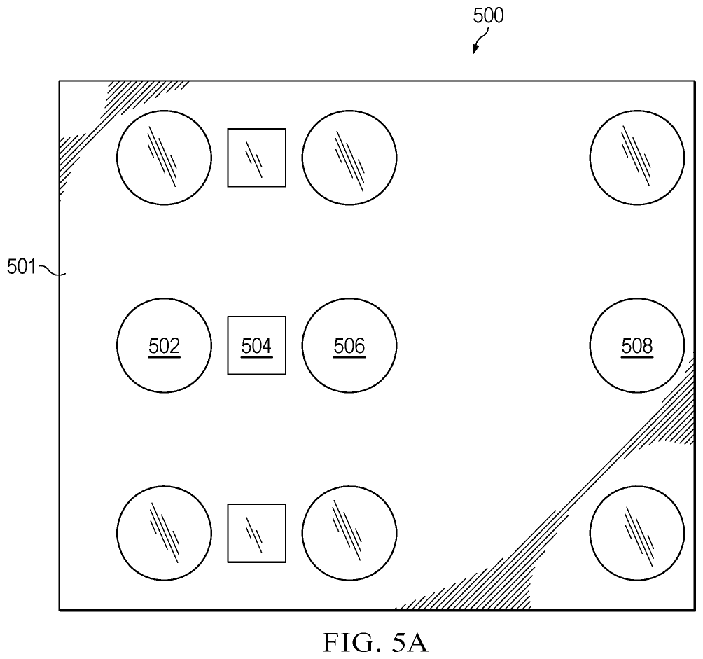

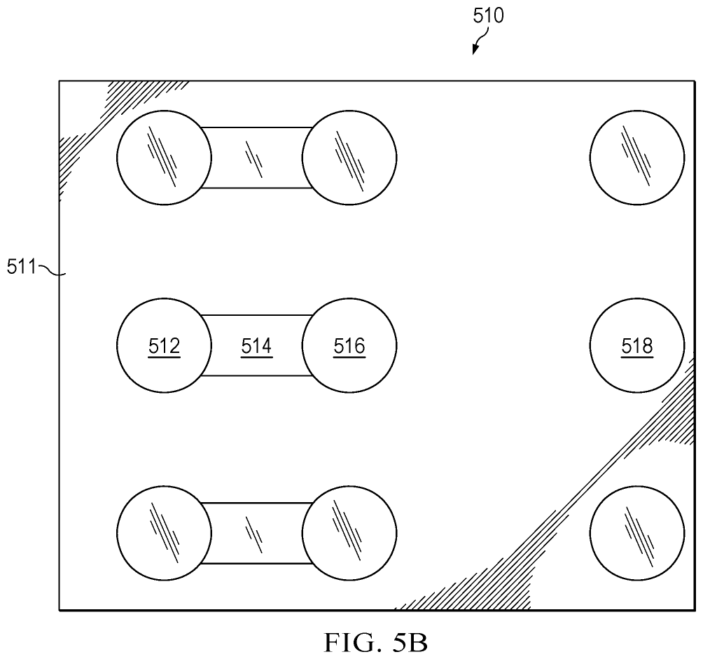

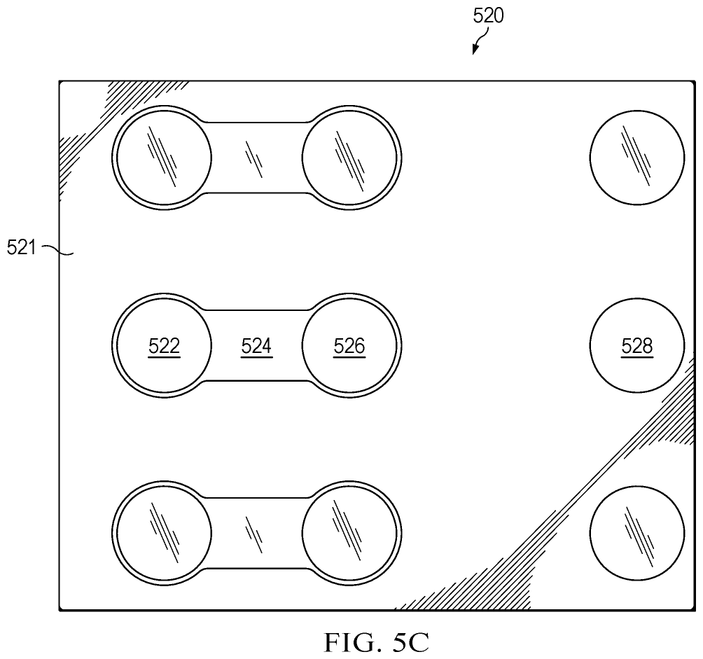

FIGS. 5A-5C are top-down views of photolithography reticles, in accordance with various examples. Each of the example reticles in FIGS. 5A-5C has a different layout of LTAs. The reticles shown in FIGS. 5A-5C may be identical to, similar to, or different from the reticle 400 of FIG. 4. The reticles of any of FIGS. 4 and 5A-5C may be modified to achieve specific target polyimide layer 300 thicknesses. In FIG. 5A, an example reticle 500 includes LTAs 501, 502, 504, 506, and 508. The LTA 501 has a light transmittance in the range of 95% to 100%, so as to transmit adequate light to protect the regions of polyimide layer 300 directly below the LTA 501. The LTAs 502, 506, and 508 have light transmittances in the range of 0% to 5%, so as to transmit minimal or no light, thereby causing the regions of polyimide layer 300 directly below the LTAs 502, 506, and 508 to be vulnerable to subsequent development and removal. The LTA 504 has a light transmittance in the range of 45% to 50%, such that the region of the polyimide layer 300 directly below the LTA 504 is partially, but not completely, removed. The LTA 501 separates the LTAs 502, 504, 506, and 508 from each other, as shown.

In FIG. 5B, an example reticle 510 includes LTAs 511, 512, 514, 516, and 518. The LTA 511 has a light transmittance in the range of 95% to 100% so as to transmit adequate light to protect the regions of polyimide layer 300 directly below the LTA 511. The LTAs 512, 516 and 518 have light transmittances in the range of 0% to 5% so as to transmit minimal or no light, thereby causing the regions of polyimide layer 300 directly below the LTAs 512, 516 and 518 to be vulnerable to subsequent development and removal. The LTA 514 has a light transmittance in the range of 45% to 50% such that the region of the polyimide layer 300 directly below the LTA 514 is partially, but not completely, removed. Unlike in the reticle 500, in the reticle 510, the LTA 514 extends between the LTAs 512 and 516 with no segments of the LTA 511 therebetween. In examples, the LTA 514 at least partially encircles each of the LTAs 512 and 516. The reticle 400 (FIG. 4) may be most similar to the reticle 510 (FIG. 5B), compared to the reticles of FIGS. 5A and 5C.

In FIG. 5C, an example reticle 520 includes LTAs 521, 522, 524, 526, and 528. The LTA 521 has a light transmittance in the range of 95% to 100% so as to transmit adequate light to protect the regions of polyimide layer 300 directly below the LTA 521. The LTAs 522, 526, and 528 have light transmittances in the range of 0% to 5% so as to transmit minimal or no light, thereby causing the regions of the polyimide layer 300 directly below the LTAs 522, 526, and 528 to be vulnerable to subsequent development and removal. The LTA 524 has a light transmittance in the range of 45% to 50% such that the region of the polyimide layer 300 directly below the LTA 524 is partially, but not completely, removed. Unlike in the reticles 500 and 510, in the reticle 520, the LTA 524 extends between the LTAs 522 and 526 and fully encircles each of the LTAs 522 and 526, as shown.

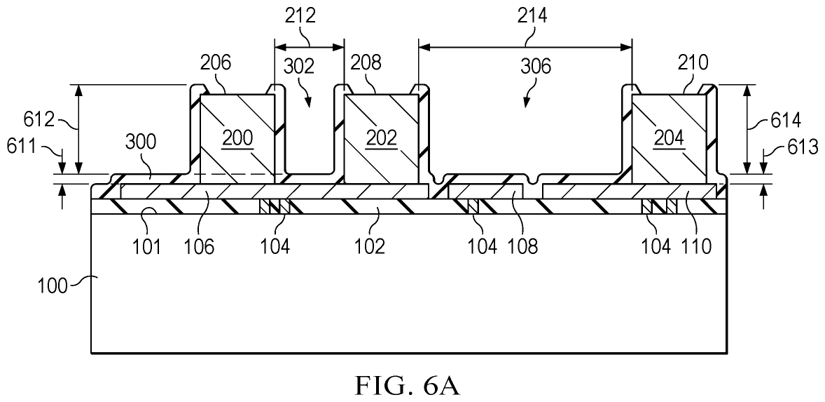

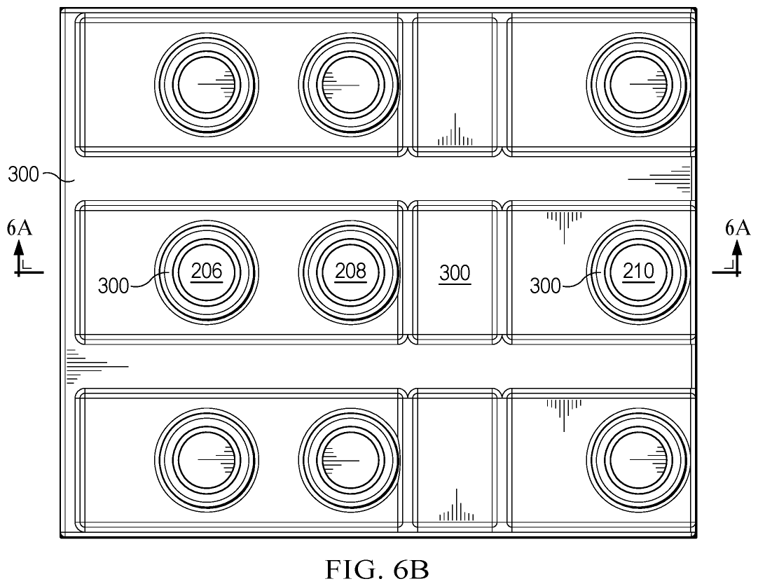

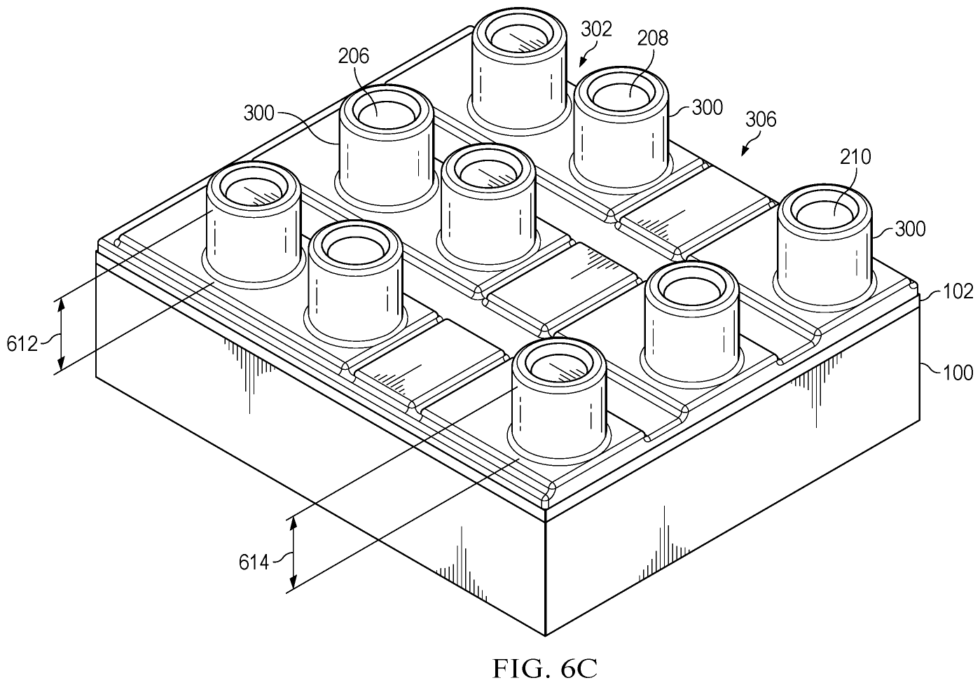

The method 1000 includes developing the polyimide layer (1012). FIG. 6A is a profile cross-sectional view of an exposed and developed protective layer on conductive terminals coupled to a BEOL layer on a semiconductor die, in accordance with various examples. More specifically, FIG. 6A shows the structure of FIG. 3A after the photolithography techniques described above have been applied using the example reticle 500 of FIG. 5A. As a result, portions of the polyimide layer 300 have been removed, exposing the top surfaces 206, 208, and 210. However, the polyimide layer 300 still covers the entire circumferences of the top surfaces 206, 208, and 210, as is especially apparent in FIG. 6B. Further, the region of polyimide layer 300 between the metal pillars 200 and 202 has been thinned, resulting in a thickness 611 ranging between 5 microns and 15 microns. The region of the polyimide layer 300 between the metal pillars 200 and 202 has been trimmed using any of the example reticles described herein instead of making multiple passes by a traditional photolithography technique employing a traditional reticle. Thus, the boundary line that would otherwise be present between adjacent layers of polyimide caused by multiple photolithography passes is absent in the examples described herein. The thickness 613 of the polyimide layer 300 in the depression 306 remains the same as before (e.g., the thickness 307 in FIG. 3A). The depression 302 has a depth 612 ranging from 30 microns to 50 microns, and the depression 306 has a depth 614 that is the same as before (e.g., the depth 308 in FIG. 3A). FIG. 6B is a top-down view of the structure of FIG. 6A, in accordance with various examples. FIG. 6C is a perspective view of the structure of FIG. 6A, in accordance with various examples.

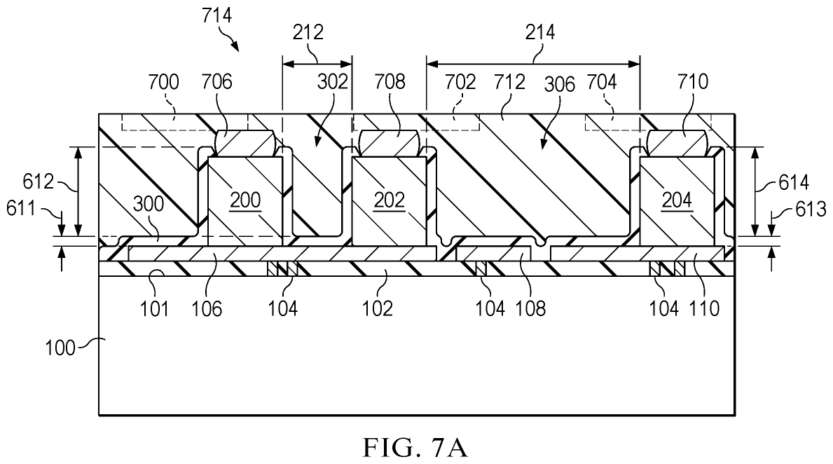

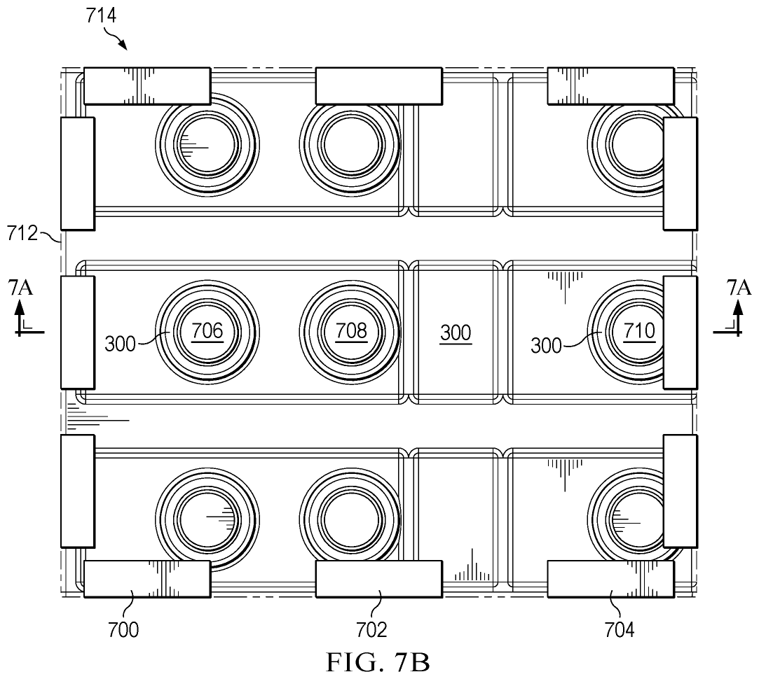

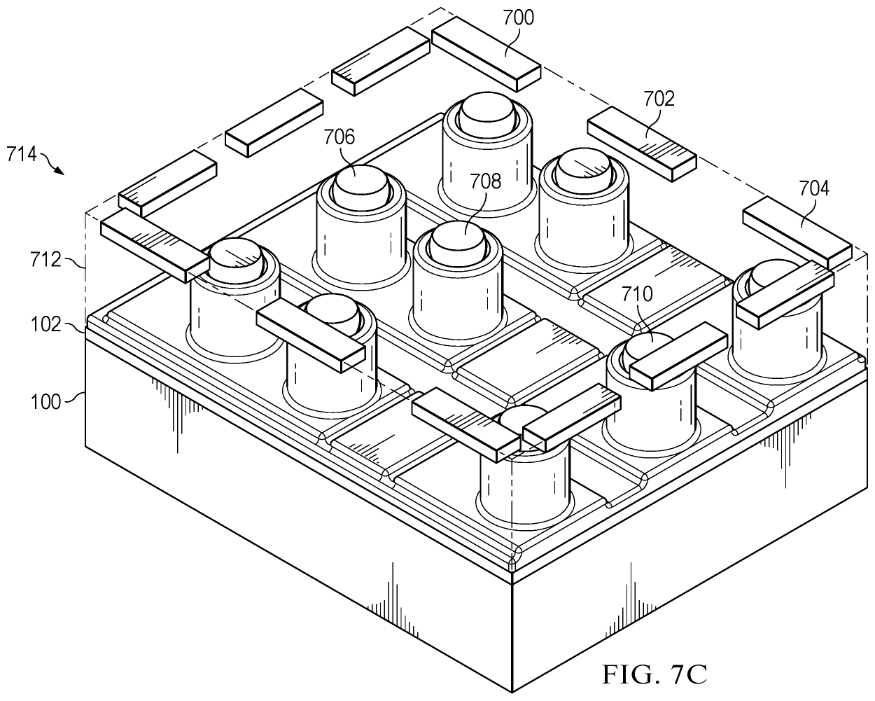

The method 1000 includes soldering the first and second metal pillars to conductive terminals (1014) and covering the semiconductor die and the polyimide layer with a mold compound (1016). FIG. 7A is a profile cross-sectional view of a semiconductor package containing a semiconductor die coupled to a BEOL layer and conductive terminals protected by a protective layer, in accordance with various examples. More specifically, FIG. 7A shows the structure of FIG. 6A, but with the coupling of the top surfaces 206, 208, and 210 of the metal pillars 200, 202, and 204, respectively, to conductive terminals (e.g., leads or pins) 700, 702, and 704 by way of solder bumps 706, 708, and 710, respectively. The solder bumps 706, 708, and 710 have thicknesses ranging from 10 microns to 60 microns, with thicker solder bumps being disadvantageous because they are prone to solder wicking or creeping on the sides of the pillars, and with thinner solder bumps being disadvantageous because they are prone to poor soldering and/or failure to wet. The conductive terminals 700, 702, and 704 are shown in dashed lines in FIG. 7A because these conductive terminals may not be in the cross-sectional plane of FIG. 7A. A mold compound 712 covers all structures shown in FIG. 7A. Consequently, a semiconductor package 714, such as a quad flat no lead (QFN) type package, is formed. FIG. 7B is a bottom-up view of the semiconductor package 714, in accordance with various examples. FIG. 7C is a perspective view of the semiconductor package 714, in accordance with various examples.

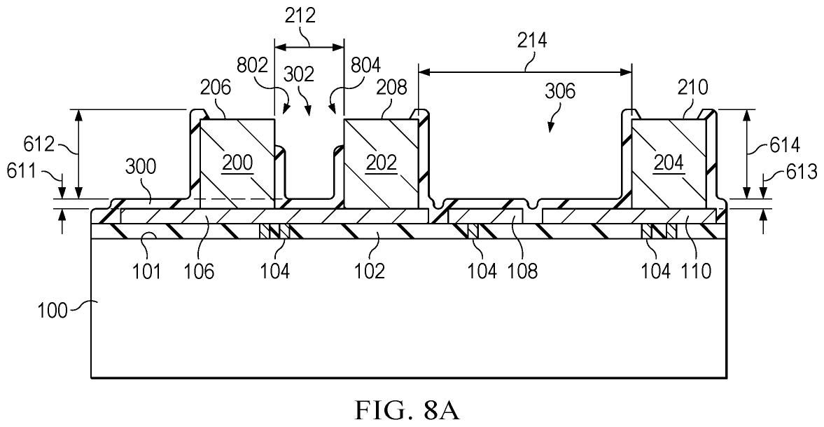

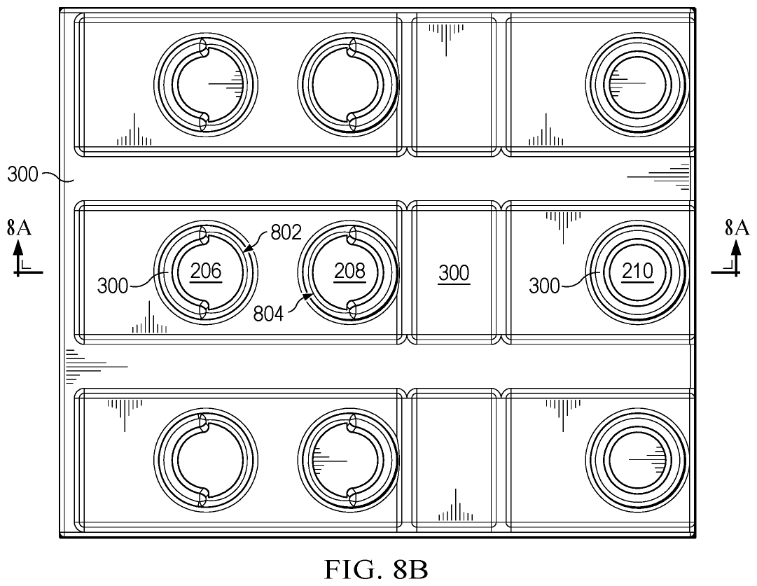

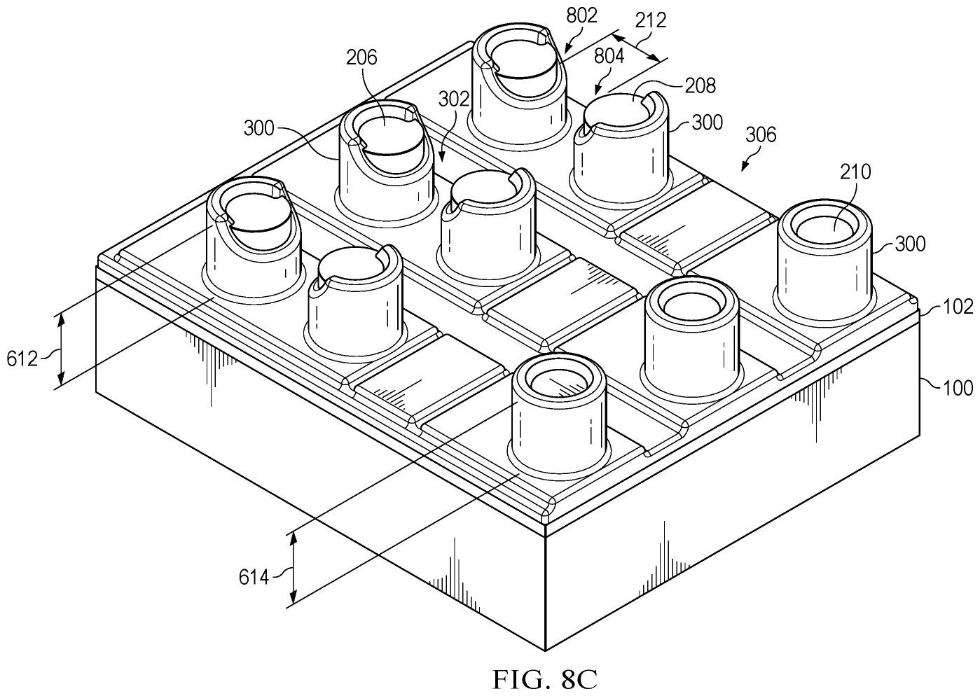

As described above, the structure of FIG. 6A shows the structure of FIG. 3A after the photolithography techniques described above have been applied using the example reticle 500 of FIG. 5A. The reticles 510 and 520 of FIGS. 5B and 5C, respectively, may modify the structure of FIG. 3A differently than shown in FIG. 6A. For example, FIG. 8A is a profile cross-sectional view of an exposed and developed protective layer on conductive terminals coupled to a BEOL layer on a semiconductor die, in accordance with various examples. More specifically, FIG. 8A shows the structure of FIG. 3A after the photolithography techniques described above have been applied using the example reticle 510 of FIG. 5B. Because the LTA 514 partially encircles the LTAs 512 and 516 (in contrast to the reticle 500 of FIG. 5A, in which the LTA 504 is separated from the LTAs 502 and 506 by the LTA 501), in FIG. 8A, the polyimide layer 300 has a reduced height in areas 802 and 804, such that in these areas 802 and 804, the polyimide layer 300 does not cover the top surfaces 206, 208, and 210. FIG. 8B is a top-down view of the structure of FIG. 8A, in accordance with various examples. FIG. 8C is a perspective view of the structure of FIG. 8A, in accordance with various examples. The structure of FIGS. 8A-8C may be coupled to conductive terminals (e.g., conductive terminals 700, 702, 704 in FIG. 7A) by solder bumps (e.g., solder bumps 706, 708, 710 in FIG. 7A) and subsequently covered by a mold compound (the mold compound 712 in FIG. 7A).

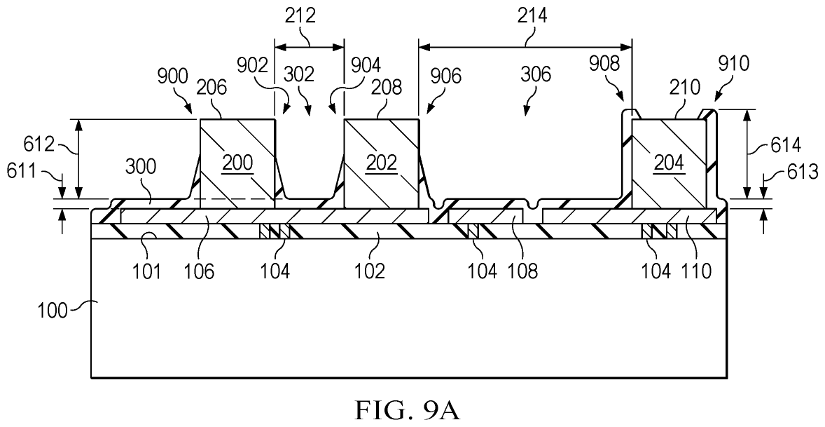

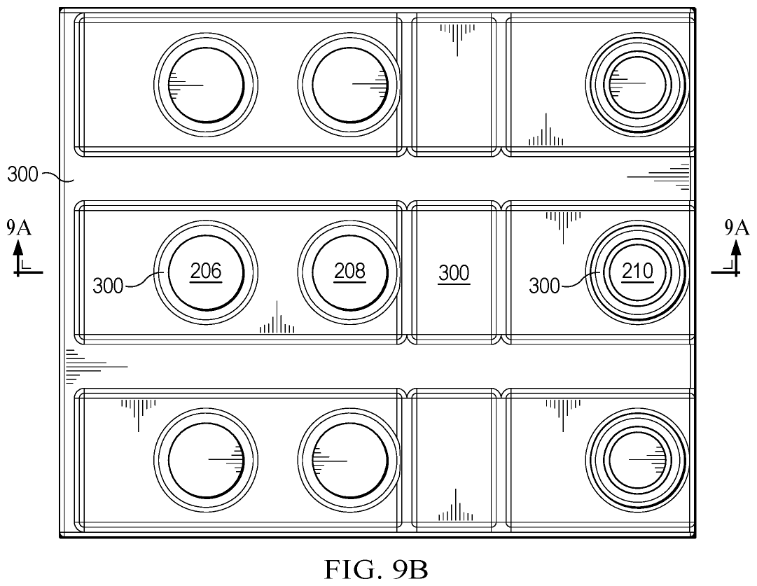

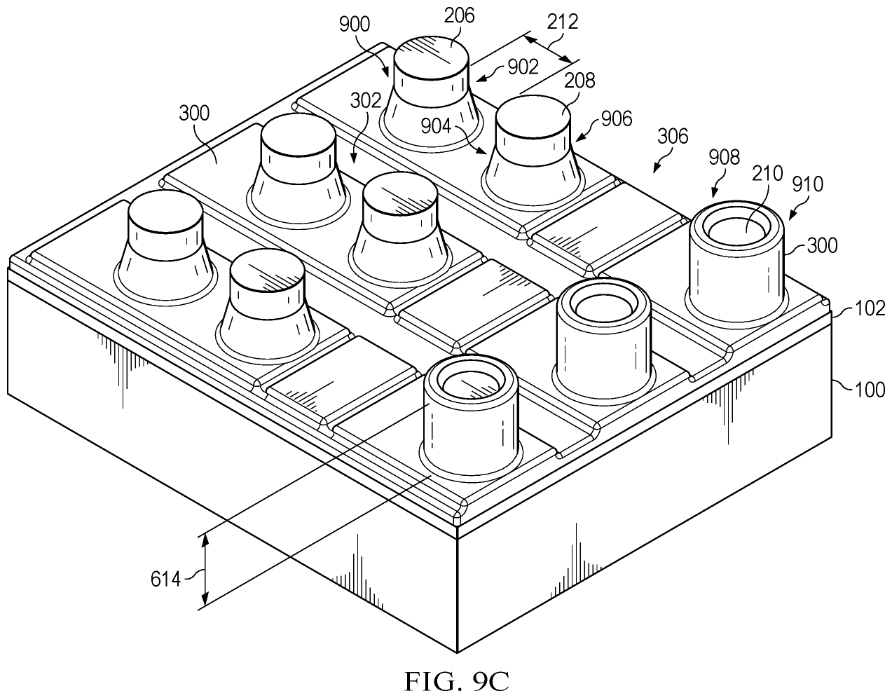

FIG. 9A is a profile cross-sectional view of an exposed and developed protective layer on conductive terminals coupled to a BEOL layer on a semiconductor die, in accordance with various examples. More specifically, FIG. 9A shows the structure of FIG. 3A after the photolithography techniques described above have been applied using the example reticle 520 of FIG. 5C. Because the LTA 524 fully encircles the LTAs 522 and 526 (in contrast to the reticle 500 of FIG. 5A, in which the LTA 504 is separated from the LTAs 502 and 506 by the LTA 501, and in contrast to the reticle 510 of FIG. 5B, in which the LTA 514 only partially encircles each of the LTAs 512 and 516), in FIG. 9A, the polyimide layer 300 has a reduced height in areas 900, 902, 904, and 906, such that in these areas the polyimide layer 300 does not cover the top surfaces 206 and 208. Areas 908 and 910 include portions of the polyimide layer 300 that contact the top surface 210. FIG. 9B is a top-down view of the structure of FIG. 9A, in accordance with various examples. FIG. 9C is a perspective view of the structure of FIG. 9A, in accordance with various examples. The structure of FIGS. 9A-9C may be coupled to conductive terminals (e.g., conductive terminals 700, 702, 704 in FIG. 7A) by solder bumps (e.g., solder bumps 706, 708, 710 in FIG. 7A) and subsequently covered by a mold compound (the mold compound 712 in FIG. 7A).

In this description, the term “couple” may cover connections, communications or signal paths that enable a functional relationship consistent with this description. For example, if device A provides a signal to control device B to perform an action, then: (a) in a first example, device A is directly connected to device B; or (b) in a second example, device A is coupled to device B through intervening component C if intervening component C does not alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die including circuitry;
a first metal pillar coupled to the circuitry and extending away from the semiconductor die;
a second metal pillar coupled to the circuitry and extending away from the semiconductor die, a distance between the first and second metal pillars not exceeding 100 microns;
a polyimide layer covering portions of the first and second metal pillars and covering a region between the first and second metal pillars, the polyimide layer in the region between the first and second metal pillars having a thickness not exceeding 15 microns and lacking a boundary between separate applications of polyimide to the region;
a mold compound covering the polyimide layer in the region between the first and second metal pillars; and
conductive terminals coupled to the first and second metal pillars and exposed to an exterior of the mold compound.

2. The semiconductor package of claim 1, wherein the first metal pillar is coupled to a metal layer and the metal layer is coupled to the circuitry, and wherein the polyimide layer at least partially covers the metal layer.

3. The semiconductor package of claim 2, wherein the metal layer has a thickness ranging between 4 microns and 25 microns, the first and second metal pillars have thicknesses ranging from 10 microns to 80 microns, and solder bumps on the first and second metal pillars have thicknesses ranging from 10 microns to 60 microns.

4. The semiconductor package of claim 3, wherein the semiconductor die includes tungsten or copper-filled vias having diameters in the range of 0.5 microns to 10 microns.

5. The semiconductor package of claim 4, wherein the semiconductor package is a quad flat no lead (QFN) type package.

6. The semiconductor package of claim 1, wherein the polyimide layer completely covers circumferences of top surfaces of the first and second metal pillars and has a depression in the region between the first and second metal pillars.

7. The semiconductor package of claim 1, wherein the polyimide layer in the region between the first and second metal pillars has a thickness ranging between 5 microns and 15 microns, and wherein the polyimide layer covers part, but not all, of a circumference of a top surface of the first metal pillar and part, but not all, of a circumference of a top surface of the second metal pillar.

8. The semiconductor package of claim 1, wherein the polyimide layer does not cover any of top surfaces of the first and second metal pillars, and wherein the polyimide layer in the region between the first and second metal pillars has a thickness ranging between 5 microns and 15 microns.

9. The semiconductor package of claim 1, wherein the mold compound has a filler size ranging from 10 microns to 30 microns.

10. A semiconductor package, comprising:
a semiconductor die including circuitry;
a first metal pillar coupled to the circuitry and extending away from the semiconductor die;
a second metal pillar coupled to the circuitry and extending away from the semiconductor die, a distance between the first and second metal pillars not exceeding 100 microns;
a polyimide layer covering portions of the first and second metal pillars and covering a region between the first and second metal pillars, the polyimide layer in the region between the first and second metal pillars lacking a boundary between separate applications of polyimide to the region;
a mold compound covering the polyimide layer in the region between the first and second metal pillars; and
conductive terminals coupled to the first and second metal pillars and exposed to an exterior of the mold compound,
wherein the polyimide layer in the region between the first and second metal pillars has a thickness ranging between 5 microns and 15 microns, and wherein the polyimide layer covers part, but not all, of a circumference of a top surface of the first metal pillar and part, but not all, of a circumference of a top surface of the second metal pillar.

11. The semiconductor package of claim 10, wherein the semiconductor package is a quad flat no lead (QFN) type package.

12. The semiconductor package of claim 10, wherein the first metal pillar is coupled to a metal layer and the metal layer is coupled to the circuitry, and wherein the polyimide layer at least partially covers the metal layer.

13. The semiconductor package of claim 10, wherein the mold compound has a filler size ranging from 10 microns to 30 microns.

14. A method for manufacturing a semiconductor package, comprising:
forming one or more metal layers in a semiconductor die, the one or more metal layers coupled to circuitry of the semiconductor die;
forming first and second metal pillars on the one or more metal layers, the first metal pillar separated from the second metal pillar by a distance not exceeding 100 microns;
applying a polyimide layer to the one or more metal layers and to the first and second metal layers;
positioning a reticle above the polyimide layer, the reticle including a first transmittance area positioned above an area of the polyimide layer on the one or more metal layers, a second transmittance area positioned above the polyimide layer on the first metal pillar, and a third transmittance area above the polyimide layer on a region between the first and second metal pillars, the third transmittance area having a light transmittance that is in between light transmittances of the first and second transmittance areas;
applying light to the polyimide layer through the first, second, and third transmittance areas of the reticle;
developing the polyimide layer;
soldering the first and second metal pillars to conductive terminals; and
covering the semiconductor die and the polyimide layer with a mold compound.

15. The method of claim 14, wherein the polyimide layer in the region between the first and second metal pillars has a thickness not exceeding 15 microns.

16. The method of claim 14, wherein the first transmittance area has a 95%-100% light transmittance.

17. The method of claim 16, wherein the second transmittance area has a 0%-5% light transmittance.

18. The method of claim 17, wherein the third transmittance area has a 40%-50% light transmittance.

19. The method of claim 14, further comprising a fourth transmittance area positioned above the polyimide layer on the second metal pillar, the fourth transmittance area having a 0%-5% light transmittance.

20. The method of claim 19, wherein the third transmittance area is between the second and fourth transmittance areas, and wherein the third transmittance area abuts the second and fourth transmittance areas.
